(19) United States
(12) Patent Application Publication
(10) Pub. No.: US 2024/0389235 A1
(43) Pub. Date: Nov. 21, 2024

(54) CIRCUIT MODULE

(71) Applicant: Murata Manufacturing Co., Ltd., Nagaokakyo-shi (JP)

(72) Inventor: Yoshihito OTSUBO, Nagaokakyo-shi (JP)

(21) Appl. No.: 18/790,389

(22) Filed: Jul. 31, 2024

Related U.S. Application Data
(63) Continuation of application No. PCT/JP2023/004328, filed on Feb. 9, 2023.

(30) Foreign Application Priority Data
Feb. 16, 2022 (JP) 2022-021968

(51) Int. Cl. H05K 1/14; H05K 1/11; H05K 1/18

(52) U.S. Cl. CPC H05K 1/144; H05K 1/11; H05K 1/181; H05K 2201/042; H05K 2201/10734

(57) ABSTRACT

A circuit module of the present disclosure includes a first circuit board, a second circuit board, a first electronic component, and one or more first solder balls. The first circuit board includes a first positive main surface and a first negative main surface. The first electronic component includes a third positive main surface and a third negative main surface. The one or more first solder balls have an ellipsoidal shape. The one or more first solder balls are located in an inter-board region between the first circuit board and the second circuit board. The first solder ball electrically connects the first circuit board and the second circuit board. The third positive main surface of the first electronic component is in contact with the first negative main surface of the first circuit board.

### CROSS REFERENCE TO RELATED APPLICATION

This is a continuation of International Application No. PCT/JP2023/004328 filed on Feb. 9, 2023 which claims priority from Japanese Patent Application No. 2022-021968 filed on Feb. 16, 2022. The contents of these applications are incorporated herein by reference in their entireties.

### BACKGROUND OF THE DISCLOSURE

### Field of the Disclosure

The present disclosure relates to a circuit module including an upper circuit board and a lower circuit board.

### Description of the Related Art

As an a disclosure related to a conventional circuit module, for example, a module described in Patent Literature 1 is known. This module has a structure in which a first mounting board and a second mounting board arranged in the up-down direction are connected by columnar pins. The module includes a first electronic component and a second electronic component located between the two mounting boards. The first electronic component is provided on the first mounting board. The second electronic component is provided on the second mounting board. The first electronic component overlaps the second electronic component when viewed in the up-down direction.

### Patent Literature 1

Japanese Patent Unexamined Publication No. 2020-161508 bulletin

### BRIEF SUMMARY OF THE DISCLOSURE

Meanwhile, there is a demand for reducing the height of the module described in Patent Literature 1.

Therefore, an object of the present disclosure is to provide a circuit module capable of reducing the height.

The inventor of the present application has studied a method of reducing the height of the module of Patent Literature 1. Here, the inventor of the present application has noticed that in the module of Patent Literature 1, the length between the two mounting boards can be shortened by bringing the bottom surface of the first electronic component and the top surface of the second electronic component into contact with each other. Thus, the inventor of the present application has considered that the module can be reduced in height.

However, the length of the columnar pin in the up-down direction in the module of Patent Literature 1 may vary due to a manufacturing error. For this reason, the inventor of the present application has noticed that the length of the columnar pin in the up-down direction may be longer than the length between the two mounting boards. In this case, the bottom surface of the first electronic component is not in contact with the top surface of the second electronic component. Therefore, the inventor of the present application has considered that it is difficult to reduce the height of the module described in Patent Literature 1 including the columnar pins.

Based on the above study, the inventors of the present application conducted another study on a method capable of reducing the height of the module. As a result, the inventor of the present application conceived the following disclosure.

A circuit module according to an embodiment of the present disclosure includes: a first circuit board including a first positive main surface and a first negative main surface arranged in a Z-axis direction, the first positive main surface being located in a positive direction of a Z-axis with respect to the first negative main surface; a second circuit board including a second positive main surface and a second negative main surface arranged in the Z-axis direction, the second circuit board being located in a negative direction of the Z-axis with respect to the first circuit board and overlapping the first circuit board when viewed in the Z-axis direction, the second positive main surface being located in the positive direction of the Z-axis with respect to the second negative main surface; a first electronic component mounted on the second positive main surface, the first electronic component including a third positive main surface and a third negative main surface arranged in the Z-axis direction, the third positive main surface being located in the positive direction of the Z-axis with respect to the third negative main surface; and one or more first solder balls having an ellipsoidal shape, the one or more first solder balls being located in an inter-board region between the first circuit board and the second circuit board and electrically connecting the first circuit board and the second circuit board, in which the circuit module has a structure of (A) or (B).
(A) the third positive main surface of the first electronic component is in contact with the first negative main surface of the first circuit board.
(B) the circuit module further comprising a second electronic component mounted on the first negative main surface, the second electronic component including a fourth positive main surface and a fourth negative main surface arranged in the Z-axis direction, the fourth positive main surface being located in the positive direction of the Z-axis with respect to the fourth negative main surface, in which the third positive main surface of the first electronic component is in contact with the fourth negative main surface of the second electronic component.

Hereinafter, the positional relationship of members in the present specification will be defined. A first member to a third member are components of the circuit module. In the present specification, the first member and the second member arranged in the front-back direction indicate the following state. Both the first member and the second member are in the state of being disposed on an arbitrary straight line indicating the front-back direction when the first member and the second member are viewed in a direction perpendicular to the front-back direction. In the present specification, the first member and the second member arranged in the front-back direction when viewed in the up-down direction indicate the following state. Both the first member and the second member are disposed on an arbitrary straight line indicating the front-back direction when the first member and the second member are viewed in the up-down direction. In this case, any one of the first member and the second member is not necessarily disposed on an arbitrary straight line indicating the front-back direction when the first member and the second member are viewed from the left-right direction different from the up-down direction. Note that the first member and the second member may be in contact with each other. The first member and the second member may be separated from each other. The third member may be present between the first member and the second member. This definition also applies to directions other than the front-back direction.

In the present specification, the first member being disposed above the second member indicates the following state. At least a part of the first member is located directly above the second member. Therefore, when viewed in the up-down direction, the first member overlaps the second member. This definition also applies to directions other than the up-down direction.

In the present specification, the first member being disposed higher than the second member includes a case where at least a part of the first member is located directly above the second member and a case where the first member is located diagonally above the second member without being located directly above the second member. In this case, the first member may not overlap the second member when viewed in the up-down direction. The term “diagonally above” means, for example, upper left and upper right. This definition also applies to directions other than the up-down direction.

In the present specification, each portion of the first member is defined as follows unless otherwise specified. A front portion of the first member means the front half of the first member. A back portion of the first member means the back half of the first member. A left portion of the first member means the left half of the first member. A right portion of the first member means the right half of the first member. An upper portion of the first member means the upper half of the first member. A lower portion of the first member means the lower half of the first member. A front end of the first member means an end of the first member in the forward direction. A back end of the first member means an end of the first member in the backward direction. A left end of the first member means an end of the first member in the leftward direction. A right end of the first member means an end of the first member in the rightward direction. An upper end of the first member means an end of the first member in the upward direction. A lower end of the first member means an end of the first member in the downward direction. A front end portion of the first member means a front end of the first member and the vicinity thereof. A back end portion of the first member means a back end of the first member and the vicinity thereof. A left end portion of the first member means a left end of the first member and the vicinity thereof. A right end portion of the first member means a right end of the first member and the vicinity thereof. An upper end portion of the first member means an upper end of the first member and the vicinity thereof. A lower end portion of the first member means a lower end of the first member and the vicinity thereof.

When any two members in the present specification are defined as the first member and the second member, a relationship between any two members has the following meaning. In the present specification, the first member being supported by the second member includes a case where the first member is attached to the second member so as to be immovable with respect to the second member (that is, it is fixed) and a case where the first member is attached to the second member so as to be movable with respect to the second member. The first member being supported by the second member further includes both of a case where the first member is directly attached to the second member and a case where the first member is attached to the second member with the third member interposed therebetween.

In the present specification, the first member being held by the second member includes a case where the first member is attached to the second member so as to be immovable with respect to the second member (that is, it is fixed), and does not include a case where the first member is attached to the second member so as to be movable with respect to the second member. The first member being held by the second member further includes both of a case where the first member is directly attached to the second member and a case where the first member is attached to the second member with the third member interposed therebetween.

In the present specification, “the first member and the second member are electrically connected” means that electricity is conducted between the first member and the second member. Therefore, the first member and the second member may be in contact with each other, or the first member and the second member may not be in contact with each other. When the first member and the second member are not in contact with each other, the third member having conductivity is disposed between the first member and the second member.

According to the circuit module of the present disclosure, the height of the circuit module can be reduced.

### BRIEF DESCRIPTION OF THE SEVERAL VIEWS OF THE DRAWINGS

FIG. 1 is a cross-sectional view of a circuit module 10.

FIG. 2 is a cross-sectional view of a circuit module 10a.

FIG. 3 is a cross-sectional view of a circuit module 10b.

FIG. 4 is a cross-sectional view of a circuit module 10c.

FIG. 5 is a cross-sectional view of a circuit module 10d.

FIG. 6 is a cross-sectional view of a circuit module 10e.

FIG. 7 is a cross-sectional view of a circuit module 10f.

FIG. 8 is a cross-sectional view of a circuit module 10g.

### DETAILED DESCRIPTION OF THE DISCLOSURE

### Embodiments

### Structure of Circuit Module

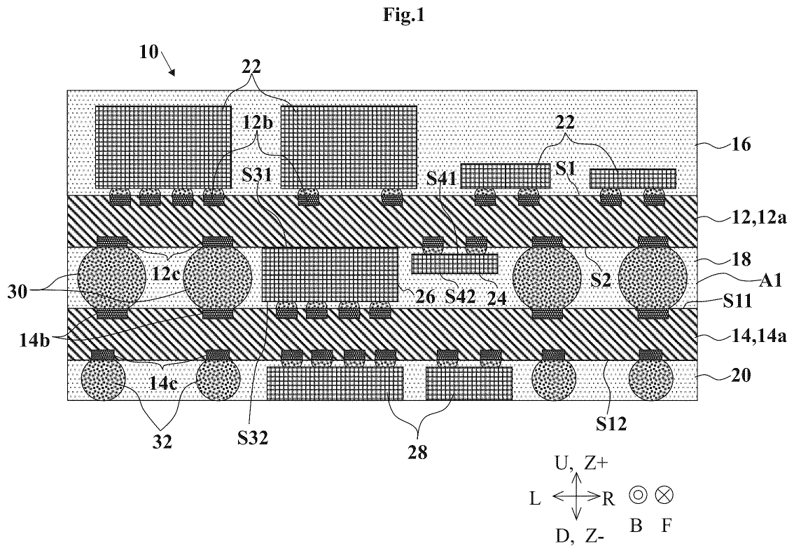

Hereinafter, a structure of a circuit module 10 according to an embodiment of the present disclosure will be described. FIG. 1 is a cross-sectional view of the circuit module 10.

Hereinafter, as illustrated in FIG. 1, a direction in which a first upper main surface S1 and a first lower main surface S2 of an upper circuit board 12 of the circuit module 10 are arranged is defined as an up-down direction. In addition, directions orthogonal to the up-down direction are defined as a front-back direction and a left-right direction. The front-back direction and the left-right direction are orthogonal to each other. The front-back direction coincides with the direction perpendicular to the paper surface of FIG. 1. The left-right direction coincides with the left-right direction of the paper surface of FIG. 1. However, the up-down direction, the left-right direction, and the front-back direction in the present specification are directions defined for convenience of description, and may not coincide with the up-down direction, the left-right direction, and the front-back direction when the circuit module 10 is used. In each drawing, the upward direction and the downward direction may be interchanged, the leftward direction and the rightward direction may be interchanged, or the forward direction and the backward direction may be interchanged.

In the present embodiment, directions are defined as illustrated in FIG. 1. The up-down direction is defined as a Z-axis direction. The upward direction is defined as a positive direction of the Z axis. The downward direction is defined as a negative direction of the Z axis. However, the Z axis direction, the positive direction of the Z axis, and the negative direction of the Z axis in the present specification are directions defined for convenience of description, and may not coincide with the Z direction, the positive direction of the Z axis, and the negative direction of the Z axis when the circuit module 10 is used.

The circuit module 10 is used for a wireless communication terminal such as a smartphone. The circuit module 10 includes, for example, a semiconductor integrated circuit (power amplifier of transmission system and low noise amplifier of reception system), a coil and/or a capacitor as a matching circuit, and the like. The circuit module 10 has a rectangular parallelepiped shape. As illustrated in FIG. 1, the circuit module 10 includes an upper circuit board 12 (first circuit board), a lower circuit board 14 (second circuit board), a second sealing resin 16, a first sealing resin 18, a third sealing resin 20, a plurality of electronic components 22, a plurality of electronic components 26, a plurality of electronic components 24, a plurality of electronic components 28, a plurality of first solder balls 30, and a plurality of second solder balls 32.

The upper circuit board 12 (first circuit board) includes a first upper main surface S1 (first positive main surface) and a first lower main surface S2 (first negative main surface) that are arranged in the up-down direction (Z-axis direction). The first upper main surface S1 (first positive main surface) is located higher than (in the positive direction of the Z-axis with respect to) the first lower main surface S2 (first negative main surface). The upper circuit board 12 includes a board body 12a, a plurality of mounting electrodes 12b, and a plurality of mounting electrodes 12c. The board body 12a has a plate shape having the first upper main surface S1 and the first lower main surface S2. The board body 12a has a rectangular shape having two sides extending in the front-back direction and two sides extending in the left-right direction when viewed in the up-down direction. The board body 12a has a multilayer structure. An electric circuit (not illustrated) is provided inside the board body 12a. The material of the board body 12a is, for example, a glass-epoxy board or an LTCC-based board.

The plurality of mounting electrodes 12b are provided on the first upper main surface S1. The plurality of mounting electrodes 12c are provided on the first lower main surface S2. The plurality of mounting electrodes 12b and the plurality of mounting electrodes 12c have a rectangular shape or a circular shape when viewed in the up-down direction. The plurality of mounting electrodes 12b and the plurality of mounting electrodes 12c have, for example, a structure in which Ni plating and Au plating are applied to the surface of the copper thin film.

The lower circuit board 14 (second circuit board) includes a second upper main surface S11 (second positive main surface) and a second lower main surface S12 (second negative main surface) arranged in the up-down direction (Z-axis direction). The second upper main surface S11 (second positive main surface) is located higher than (in the positive direction of the Z axis with respect to) the second lower main surface S12 (second negative main surface). The lower circuit board 14 includes a board body 14a, a plurality of mounting electrodes 14b, and a plurality of mounting electrodes 14c. The board body 14a has a plate shape having the second upper main surface S11 and the second lower main surface S12. The board body 14a has a rectangular shape having two sides extending in the front-back direction and two sides extending in the left-right direction when viewed in the up-down direction. The board body 14a has a multilayer structure. An electric circuit (not illustrated) is provided inside the board body 14a. The material of the board body 14a is, for example, a glass-epoxy board or an LTCC-based board.

The plurality of mounting electrodes 14b are provided on the second upper main surface S11. The plurality of mounting electrodes 14c are provided on the second lower main surface S12. The plurality of mounting electrodes 14b and the plurality of mounting electrodes 14c have a rectangular shape or a circular shape when viewed in the up-down direction. The plurality of mounting electrodes 14b and the plurality of mounting electrodes 14c have a structure in which, for example, Ni plating and Au plating are applied to the surface of a copper thin film.

In the present embodiment, the lower circuit board 14 (second circuit board) is located lower than (in the negative direction of the Z axis with respect to) the upper circuit board 12 (first circuit board). The lower circuit board 14 (second circuit board) overlaps the upper circuit board 12 (first circuit board) when viewed in the up-down direction (along the Z-axis). When viewed in the up-down direction, the entire outer edge of the lower circuit board 14 overlaps the entire outer edge of the upper circuit board 12.

The plurality of first solder balls 30 have an ellipsoidal shape. In the present embodiment, the plurality of first solder balls 30 have a spherical shape. The plurality of first solder balls 30 are located in an inter-board region Al between the upper circuit board 12 (first circuit board) and the lower circuit board 14 (second circuit board). The plurality of first solder balls 30 electrically connect the upper circuit board 12 (first circuit board) and the lower circuit board 14 (second circuit board). Specifically, the plurality of first solder balls 30 are provided on the first lower main surface S2 and the second upper main surface S11. More precisely, the plurality of first solder balls 30 are in contact with the plurality of mounting electrodes 12c of the upper circuit board 12 and the plurality of mounting electrodes 14b of the lower circuit board 14. The plurality of first solder balls 30 are solder bumps.

The plurality of second solder balls 32 have an ellipsoidal shape. In the present embodiment, the plurality of second solder balls 32 have a spherical shape. The plurality of second solder balls 32 are provided on the second lower main surface S12 (second negative main surface) of the lower circuit board 14 (second circuit board). More precisely, the plurality of second solder balls 32 are provided on the plurality of mounting electrodes 14c. Accordingly, in the present embodiment, the first solder balls 30 and the plurality of second solder balls 32 are arranged in this order in the negative direction of the Z-axis. The plurality of second solder balls 32 come into contact with a mounting electrode of a motherboard when the circuit module 10 is mounted on the motherboard. That is, the plurality of second solder balls 32 are solder bumps.

The size of the first solder ball 30 is larger than the size of the second solder ball 32. In the present embodiment, the plurality of first solder balls 30 and the plurality of second solder balls 32 are provided. Accordingly, the size of the first solder balls 30 is an average value of the sizes of the plurality of first solder balls 30. The size of the second solder ball 32 is an average value of the sizes of the plurality of second solder balls 32. In the present embodiment, the first solder ball 30 and the second solder ball 32 have spherical shapes. Therefore, the size of the first solder ball 30 is the diameter of the first solder ball 30. The size of the second solder ball 32 is a diameter of the second solder ball 32. When the first solder ball 30 has an ellipsoidal shape, the size of the first solder ball 30 is the maximum diameter of the first solder ball 30. When the second solder ball 32 has an ellipsoidal shape, the size of the second solder ball 32 is the maximum diameter of the second solder ball 32.

The plurality of electronic components 22 are mounted on the first upper main surface S1. That is, the plurality of electronic components 22 are mounted on the plurality of mounting electrodes 12b.

The plurality of electronic components 24 (second electronic components) are mounted on the first lower main surface S2 (first negative main surface). That is, the plurality of electronic components 24 are mounted on the plurality of mounting electrodes 12c. The electronic component 24 (second electronic component) includes a fourth upper main surface S41 (fourth positive main surface) and a fourth lower main surface S42 (fourth negative main surface) arranged in the up-down direction (Z-axis direction). The fourth upper main surface S41 (fourth positive main surface) is located higher than (in the positive direction of the Z axis with respect to) the fourth lower main surface S42 (fourth negative main surface). The plurality of electronic components 24 are not in contact with the lower circuit board 14. Specifically, the fourth lower main surfaces S42 of the plurality of electronic components 24 are not in contact with the second upper main surface S11 of the lower circuit board 14. In the present embodiment, the plurality of electronic components 24 and the plurality of second solder balls 32 are arranged in this order in the negative direction of the Z-axis.

The plurality of electronic components 26 (first electronic components) are mounted on the second upper main surface S11 (second positive main surface). That is, the plurality of electronic components 26 are mounted on the plurality of mounting electrodes 14b. The electronic component 26 (first electronic component) includes a third upper main surface S31 (third positive main surface) and a third lower main surface S32 (third negative main surface) arranged in the up-down direction (Z-axis direction). The third upper main surface S31 (third positive main surface) is located higher than (in the positive direction of the Z axis with respect to) the third lower main surface S32 (third negative main surface). The plurality of electronic components 26 do not overlap the plurality of electronic components 24 when viewed in the up-down direction. The plurality of electronic components 26 are in contact with the upper circuit board 12. Specifically, the third upper main surfaces S31 (third positive main surfaces) of the plurality of electronic components 26 (first electronic components) are in contact with the first lower main surface S2 (first negative main surface) of the upper circuit board 12 (first circuit board). In the present embodiment, the plurality of electronic components 26 and the plurality of second solder balls 32 are arranged in this order in the negative direction of the Z-axis.

The plurality of electronic components 28 are mounted on the second lower main surface S12. That is, the plurality of electronic components 28 are mounted on the plurality of mounting electrodes 14c.

The plurality of electronic components 22, the plurality of electronic components 24, the plurality of electronic components 26, and the plurality of electronic components 28 as described above are electronic components such as chip coils, chip capacitors, and semiconductor integrated circuits.

The first sealing resin 18 is in contact with the first lower main surface S2 (first negative main surface) and the second upper main surface S11 (second positive main surface). The first sealing resin 18 is provided in the inter-board region Al so as to cover the surfaces of the plurality of first solder balls 30. The first sealing resin 18 covers the surfaces of the plurality of electronic components 26 and the plurality of electronic components 24. Therefore, the plurality of first solder balls 30, the plurality of electronic components 26, and the plurality of electronic components 24 are located in the first sealing resin

Here, as described above, the inter-board region Al is a region located between the upper circuit board 12 and the lower circuit board 14. The upper circuit board 12 and the lower circuit board 14 have rectangular shapes when viewed in the up-down direction. Therefore, the inter-board region Al has a rectangular parallelepiped shape. Thus, the first sealing resin 18 has a rectangular parallelepiped shape. When viewed in the up-down direction, the entire outer edge of the first sealing resin 18 overlaps the entire outer edge of the upper circuit board 12 and the entire outer edge of the lower circuit board 14. Such a first sealing resin 18 is filled in the inter-board region Al without any gap. However, slight air bubbles may remain in the first sealing resin 18.

The second sealing resin 16 covers the first upper main surface S1 (first positive main surface). The second sealing resin 16 covers the surfaces of the plurality of electronic components 22. Therefore, the plurality of electronic components 22 are located in the second sealing resin 16. The second sealing resin 16 has a rectangular parallelepiped shape. When viewed in the up-down direction, the entire outer edge of the second sealing resin 16 overlaps the entire outer edge of the upper circuit board 12 and the entire outer edge of the lower circuit board 14.

The third sealing resin 20 covers the second lower main surface S12 (second negative main surface). The third sealing resin 20 covers the surfaces of the plurality of second solder balls 32 and the side surfaces of the plurality of electronic components 28. However, the lower end portions of the plurality of second solder balls 32 and the lower surfaces of the plurality of electronic components 28 are exposed from the third sealing resin 20. Therefore, the plurality of second solder balls 32 and the plurality of electronic components 28 are located in the third sealing resin 20. The third sealing resin 20 has a rectangular parallelepiped shape. When viewed in the up-down direction, the entire outer edge of the third sealing resin 20 overlaps the entire outer edge of the upper circuit board 12 and the entire outer edge of the lower circuit board 14. The materials of the second sealing resin 16, the first sealing resin 18, and the third sealing resin 20 as described above are, for example, epoxy resins.

The manufacturing process of the circuit module 10 is as follows. The upper circuit board 12 on which the plurality of electronic components 24 and the plurality of electronic components 22 are mounted is prepared. The second sealing resin 16 is formed on the first upper main surface S1. The lower circuit board 14 on which the plurality of second solder balls 32, the plurality of electronic components 26, and the plurality of electronic components 28 are mounted is prepared. The third sealing resin 20 is formed below the second lower main surface S12. Next, the plurality of first solder balls 30 are disposed on the mounting electrodes 14b of the lower circuit board 14. Next, the third upper main surfaces S31 of the plurality of electronic components 26 and the plurality of first solder balls 30 are brought into contact with the first lower main surface S2 of the upper circuit board 12. Next, the plurality of first solder balls 30 are melted. Next, the first solder ball 30 is cooled to solidify the first solder ball 30. Finally, the first sealing resin 18 is formed between the upper circuit board 12 and the lower circuit board 14.

### Effects

According to the circuit module 10, the height of the circuit module 10 can be reduced. More specifically, in the module described in Patent Literature 1, the first mounting board and the second mounting board arranged in the up-down direction are connected by columnar pins. The length of the columnar pin in the up-down direction varies due to a manufacturing error. Therefore, the length of the columnar pin in the up-down direction may be longer than the length between the two mounting boards. In this case, the upper surface of the second electronic component is not in contact with the lower surface of the first mounting board. Therefore, it is difficult to reduce the height of the module described in Patent Literature 1.

Therefore, in the circuit module 10, the upper circuit board 12 (first circuit board) and the lower circuit board 14 (second circuit board) are electrically connected by the plurality of first solder balls 30. When the plurality of first solder balls 30 are melted in the manufacturing process, the lengths of the plurality of first solder balls 30 in the Z-axis direction slightly change. Accordingly, the length of the first solder ball 30 in the Z-axis direction is likely to be equal to a length between the upper circuit board 12 and the lower circuit board 14. Therefore, the third upper main surface S31 of the electronic component 26 is in contact with the first lower main surface S2 of the upper circuit board 12. In other words, there is no space between the third upper main surface S31 of the electronic component 26 and the first lower main surface S2 of the upper circuit board 12. Therefore, the length between the upper circuit board 12 and the lower circuit board 14 can be shortened. As a result, the height of the circuit module 10 can be reduced.

### First Modification

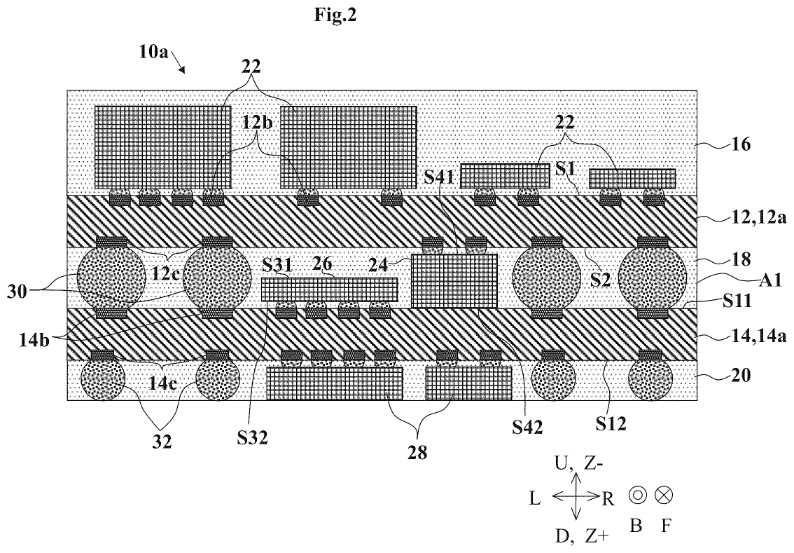

Hereinafter, a circuit module 10a according to a first modification will be described with reference to the drawings. FIG. 2 is a cross-sectional view of the circuit module 10a.

Here, the definition of the direction in the present modification is different from the definition of the direction in the first embodiment. Specifically, in the present modification, as illustrated in FIG. 2, the upward direction coincides with the negative direction of the Z axis, and the downward direction coincides with the positive direction of the Z axis. Therefore, in the present modification, the upper circuit board 12 (second circuit board) is located higher than (in the negative direction of the Z-axis with respect to) the lower circuit board 14 (first circuit board).

In the present modification, the lower circuit board 14 (first circuit board) has the second upper main surface S11 (first negative main surface) and the second lower main surface S12 (first positive main surface) that are arranged in the up-down direction (Z-axis direction). The second lower main surface S12 (first positive main surface) is located lower than (in the positive direction of the Z axis with respect to) the second upper main surface S11 (first negative main surface).

The electronic component 26 (second electronic component) is mounted on the second upper main surface S11 (first negative main surface). The electronic component 26 (second electronic component) has the third upper main surface S31 (fourth negative main surface) and the third lower main surface S32 (fourth positive main surface) arranged in the up-down direction (Z-axis direction). The third lower main surface S32 (fourth positive main surface) is located lower than (in the positive direction of the Z axis with respect to) the third upper main surface S31 (fourth negative main surface).

The upper circuit board 12 (second circuit board) has the first upper main surface S1 (second negative main surface) and the first lower main surface S2 (second positive main surface) that are arranged in the up-down direction (Z-axis direction). The first lower main surface S2 (second positive main surface) is located lower than (in the positive direction of the Z axis with respect to) the first upper main surface S1 (second negative main surface).

The electronic component 24 (first electronic component) is mounted on the first lower main surface S2 (second positive main surface). The electronic component 24 (first electronic component) has the fourth upper main surface S41 (third negative main surface) and the fourth lower main surface S42 (third positive main surface). The fourth lower main surface S42 (third positive main surface) is located lower than (in the positive direction of the Z axis with respect to) the fourth upper main surface S41 (third negative main surface).

As illustrated in FIG. 2, the circuit module 10a is different from the circuit module 10 in that the plurality of electronic components 24 are in contact with the lower circuit board 14. Specifically, the fourth lower main surfaces S42 (third positive main surfaces) of the plurality of electronic components 24 (first electronic components) are in contact with the second upper main surface S11 (first negative main surface) of the lower circuit board 14 (first circuit board). In the circuit module 10a, the plurality of second solder balls 32 are provided on the second lower main surface S12 (first positive main surface) of the lower circuit board 14 (first circuit board).

In the circuit module 10a, the plurality of second solder balls 32 are provided on the second lower main surface S12 (first positive main surface) of the lower circuit board 14 (first circuit board). Similarly to the circuit module 10, the sizes of the plurality of first solder balls 30 in the circuit module 10a are larger than the sizes of the plurality of second solder balls 32.

In the circuit module 10a, the second sealing resin 16 covers the first upper main surface S1 (second negative main surface) of the upper circuit board 12 (second circuit board). The third sealing resin 20 covers the second lower main surface S12 (first positive main surface).

Other structures of the circuit module 10a are the same as those of the circuit module 10, and thus description thereof will be omitted. The circuit module 10a has the same effect as the circuit module 10. Specifically, in the circuit module 10a, the fourth lower main surfaces S42 (third positive main surfaces) of the plurality of electronic components 24 (first electronic components) mounted on the first lower main surface S2 (second positive main surface) are in contact with the second upper main surface S11 (first negative main surface) of the lower circuit board 14 (first circuit board). Therefore, the length between the upper circuit board 12 and the lower circuit board 14 can be shortened. As a result, the height of the circuit module 10a can be reduced.

### Second Modification

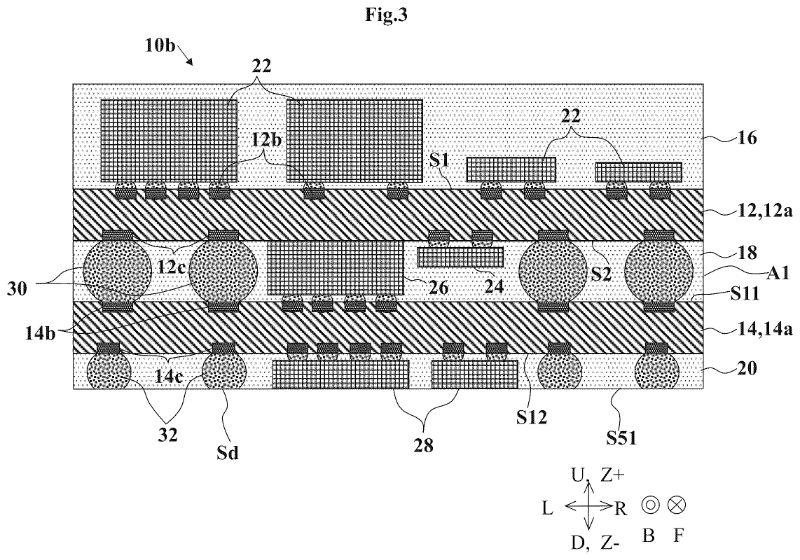

Hereinafter, a circuit module 10b according to a second modification will be described with reference to the drawings. FIG. 3 is a cross-sectional view of the circuit module 10b. The definitions of the Z-axis direction, the positive direction of the Z-axis, and the negative direction of the Z-axis in the present modification are the same as the definitions of the Z-axis direction, the positive direction of the Z-axis, and the negative direction of the Z-axis in the first embodiment.

The circuit module 10b is different from the circuit module 10 in the shape of the plurality of second solder balls 32. More specifically, the plurality of second solder balls 32 each have a bottom surface Sd that is a plane orthogonal to the up-down direction (Z-axis direction). The bottom surfaces Sd of the plurality of second solder balls 32 are included in one plane together with the lower main surface S51 of the third sealing resin 20 (negative main surface of third sealing resin 20). That is, the bottom surfaces Sd of the plurality of second solder balls 32 are flush with the lower main surface S51 of the third sealing resin 20. Such a circuit module 10b is manufactured by polishing the lower main surface S51 of the third sealing resin 20. Other structures of the circuit module 10b are the same as those of the circuit module 10, and thus description will be omitted. The circuit module 10b has the same functions and effects as those of the circuit module 10.

According to the circuit module 10b, the bottom surfaces Sd of the plurality of second solder balls 32 are exposed from the lower main surface S51 of the third sealing resin 20 (negative main surface of third sealing resin 20). Therefore, the area of the plurality of second solder balls 32 exposed from the lower main surface S51 of the third sealing resin 20 in the circuit module 10b is larger than the area of the plurality of second solder balls 32 exposed from the lower main surface S51 of the third sealing resin 20 in the circuit module 10. Therefore, according to the circuit module 10b, when the circuit module 10b is mounted on the motherboard, the circuit module 10b is more reliably electrically connected to the motherboard.

### Third Modification

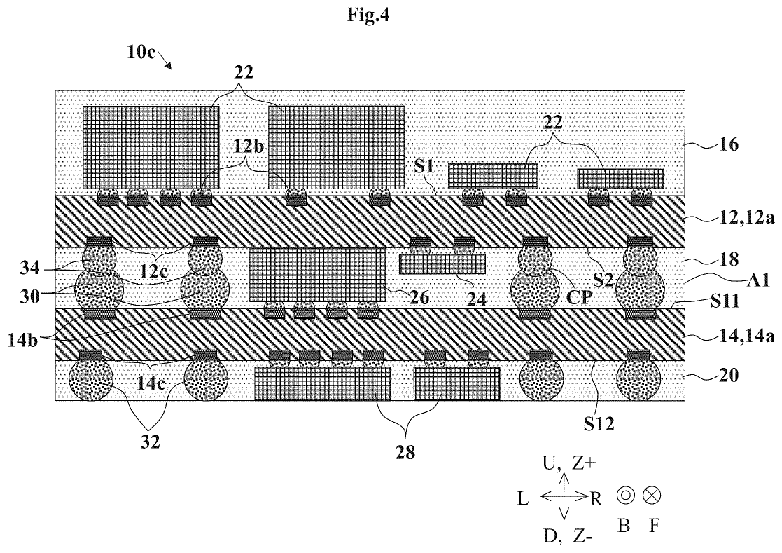

Hereinafter, a circuit module 10c according to a third modification will be described with reference to the drawings. FIG. 4 is a cross-sectional view of the circuit module 10c. The definitions of the Z-axis direction, the positive direction of the Z-axis, and the negative direction of the Z-axis in the present modification are the same as the definitions of the Z-axis direction, the positive direction of the Z-axis, and the negative direction of the Z-axis in the first embodiment.

The circuit module 10c is different from the circuit module 10 in further including a plurality of third solder balls 34. The third solder ball 34 has an ellipsoidal shape. In the present embodiment, the third solder ball 34 has a spherical shape. The plurality of third solder balls 34 are located in the inter-board region Al between the upper circuit board 12 (first circuit board) and the lower circuit board 14 (second circuit board). The plurality of third solder balls 34 electrically connect the upper circuit board 12 (first circuit board) and the lower circuit board 14 (second circuit board). Specifically, the plurality of first solder balls 30 are in contact with the mounting electrode 14b of the lower circuit board 14 (second circuit board). The plurality of third solder balls 34 are in contact with the mounting electrode 12c of the upper circuit board 12 (first circuit board). The plurality of first solder balls 30 and the plurality of third solder balls 34 are arranged in the up-down direction (Z-axis direction) and are in contact with each other. A contact portion CP where the first solder ball 30 and the third solder ball 34 are in contact with each other is surrounded by an outer edge of the first solder ball 30 and an outer edge of the third solder ball 34 when viewed in the up-down direction (Z-axis direction).

Other structures of the circuit module 10c are the same as those of the circuit module 10, and thus description will be omitted. The circuit module 10c has the same functions and effects as those of the circuit module 10.

### Fourth Modification

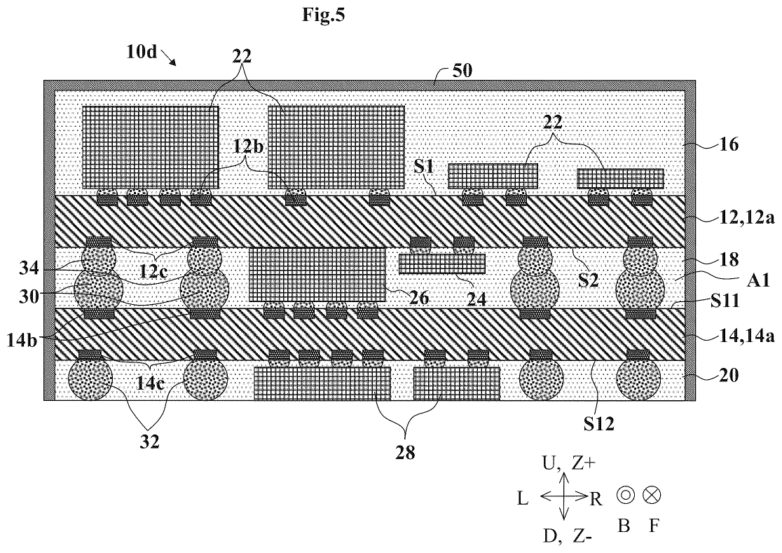

Hereinafter, a circuit module 10d according to a fourth modification will be described with reference to the drawings. FIG. 5 is a cross-sectional view of the circuit module 10d. The definitions of the Z-axis direction, the positive direction of the Z-axis, and the negative direction of the Z-axis in the present modification are the same as the definitions of the Z-axis direction, the positive direction of the Z-axis, and the negative direction of the Z-axis in the first embodiment.

The circuit module 10d is different from the circuit module 10c in further including a shield conductor 50. The shield conductor 50 covers an upper surface (positive main surface) of the second sealing resin 16 and side surfaces of the second sealing resin 16 located in a direction orthogonal to the up-down direction (Z-axis direction), side surfaces of the upper circuit board 12 (first circuit board) located in a direction orthogonal to the up-down direction (Z-axis direction), side surfaces of the first sealing resin 18 located in a direction orthogonal to the up-down direction (Z-axis direction), and side surfaces of the lower circuit board 14 (second circuit board) located in a direction orthogonal to the up-down direction (Z-axis direction). The side surfaces located in the direction orthogonal to the Z-axis direction are a front surface, a back surface, a left surface, and a right surface. The shield conductor 50 is connected to the ground potential. Other structures of the circuit module 10d are the same as those of the circuit module 10b, and thus description thereof will be omitted. The circuit module 10d has the same function and effect as the circuit module 10b.

In addition, the circuit module 10d includes the shield conductor 50 connected to the ground potential. Therefore, the emission of noise from the circuit module 10d to the outside of the circuit module 10d is suppressed, and the intrusion of noise into the circuit module 10 from the outside of the circuit module 10 is suppressed.

### Fifth Modification

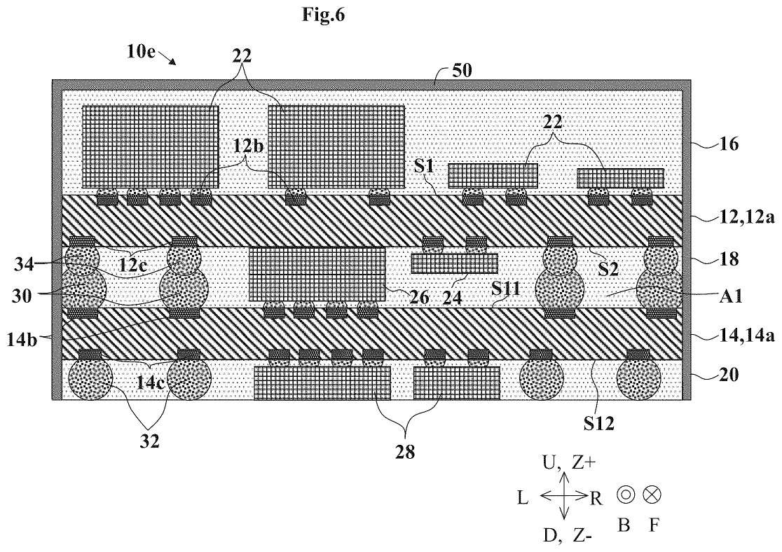

Hereinafter, a circuit module 10e according to a fifth modification will be described with reference to the drawings. FIG. 6 is a cross-sectional view of the circuit module 10e. The definitions of the Z-axis direction, the positive direction of the Z-axis, and the negative direction of the Z-axis in the present modification are the same as the definitions of the Z-axis direction, the positive direction of the Z-axis, and the negative direction of the Z-axis in the first embodiment.

The circuit module 10e is different from the circuit module 10d in that at least one of the plurality of first solder balls 30 is in contact with the shield conductor 50. In the present embodiment, two first solder balls 30 are in contact with the shield conductor 50. Other structures of the circuit module 10e are the same as those of the circuit module 10d, and thus description will be omitted. The circuit module 10e has the same functions and effects as those of the circuit module 10d. In addition, according to the circuit module 10e, the shield conductor 50 is connected to the ground potential via the first solder ball 30.

### Second Embodiment

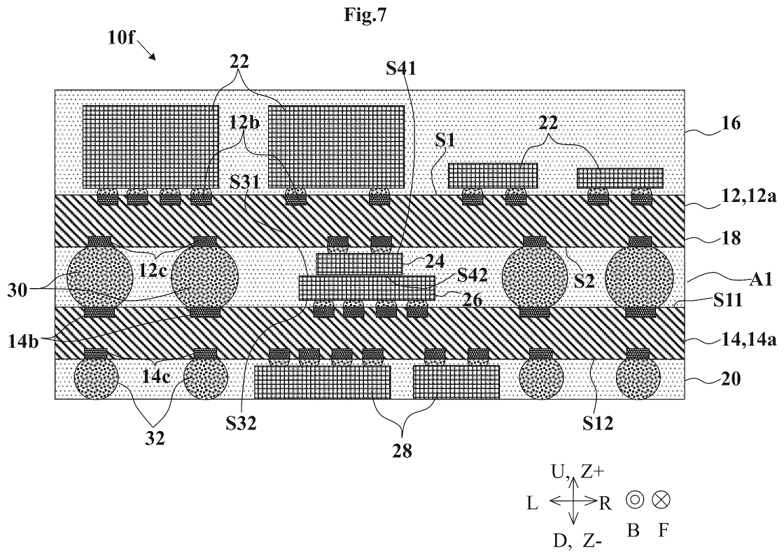

Hereinafter, a circuit module 10f according to a second embodiment will be described with reference to the drawings. FIG. 7 is a cross-sectional view of the circuit module 10f. The definitions of the Z-axis direction, the positive direction of the Z-axis, and the negative direction of the Z-axis in the present modification are the same as the definitions of the Z-axis direction, the positive direction of the Z-axis, and the negative direction of the Z-axis in the first embodiment.

As illustrated in FIG. 7, the circuit module 10f is different from the circuit module 10 in that the plurality of electronic components 26 and the plurality of electronic components 24 are in contact with each other. Specifically, the third upper main surfaces S31 (third positive main surfaces) of the plurality of electronic components 26 (first electronic components) are in contact with the fourth lower main surfaces S42 (fourth negative main surfaces) of the plurality of electronic components 24 (second electronic components).

### Effects

According to the circuit module 10f, the height of the circuit module 10f can be reduced. As described above, in the module described in Patent Literature 1, it is difficult to reduce the height of the module described in Patent Literature 1 by columnar pins. On the other hand, in the circuit module 10f, the upper circuit board 12 (first circuit board) and the lower circuit board 14 (second circuit board) are electrically connected by the plurality of first solder balls 30. Accordingly, similarly to the circuit module 10, the length of the first solder ball 30 in the Z-axis direction is equal to the length between the upper circuit board 12 (first circuit board) and the lower circuit board 14 (second circuit board). Therefore, the third upper main surface S31 (third positive main surface) of the electronic component 26 (first electronic component) is in contact with the fourth lower main surface S42 (fourth negative main surface) of the electronic component 24 (second electronic component). As a result, the height of the circuit module 10f can be reduced.

### Modification of Second Embodiment

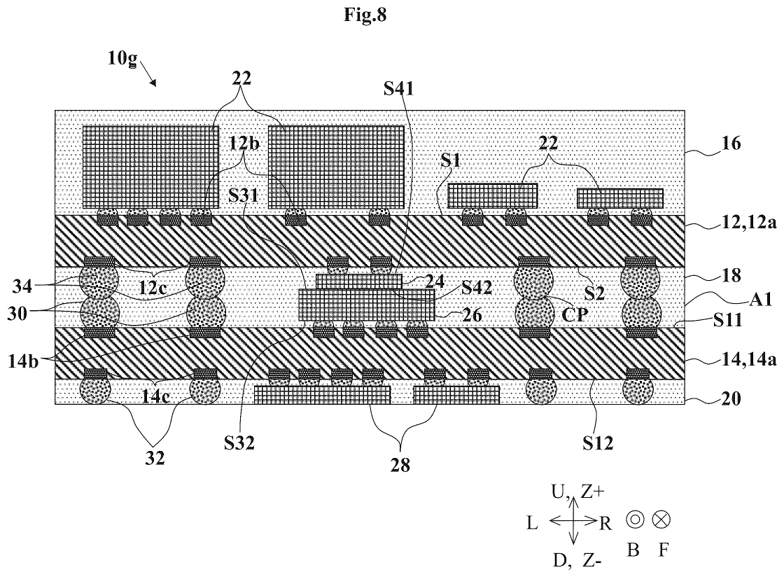

Hereinafter, a circuit module 10g according to a modification of the second embodiment will be described with reference to the drawings. FIG. 8 is a cross-sectional view of the circuit module 10g. The definitions of the Z-axis direction, the positive direction of the Z-axis, and the negative direction of the Z-axis in the present modification are the same as the definitions of the Z-axis direction, the positive direction of the Z-axis, and the negative direction of the Z-axis in the first embodiment.

The circuit module 10g is different from the circuit module 10f in further including a plurality of third solder balls 34. The third solder ball 34 has an ellipsoidal shape. The plurality of third solder balls 34 are located in the inter-board region Al between the upper circuit board 12 (first circuit board) and the lower circuit board 14 (second circuit board). The plurality of third solder balls 34 electrically connect the upper circuit board 12 (first circuit board) and the lower circuit board 14 (second circuit board). Specifically, the plurality of first solder balls 30 are in contact with the mounting electrode 14b of the lower circuit board 14 (second circuit board). The plurality of third solder balls 34 are in contact with the mounting electrode 12c of the upper circuit board 12 (first circuit board). The plurality of first solder balls 30 and the plurality of third solder balls 34 are arranged in the up-down direction (Z-axis direction) and are in contact with each other.

The contact portion CP where the first solder ball 30 and the third solder ball 34 are in contact with each other is surrounded by the outer edge of the first solder ball 30 and the outer edge of the third solder ball 34 when viewed in the Z-axis direction.

The circuit module 10g has the same functions and effects as those of the circuit module 10f.

### Other Embodiments

The circuit module according to the present disclosure is not limited to the circuit modules 10 and 10a to 10g, and can be changed within the scope of the gist thereof. In addition, the structures of the circuit modules 10 and 10a to 10g may be arbitrarily combined.

The circuit modules 10 and 10a to 10g each include the plurality of first solder balls 30. However, the circuit modules 10 and 10a to 10g each only need to include one or more first solder balls 30.

The circuit modules 10 and 10a to 10g each include the plurality of second solder balls 32. However, the circuit modules 10 and 10a to 10g each only need to include one or more second solder balls 32.

In the circuit module 10e, at least one of one or more first solder balls 30 only needs to be in contact with the shield conductor 50.

The circuit modules 10 and 10a to 10g each include the plurality of electronic components 26. However, the circuit modules 10 and 10a to 10g each only need to include one or more electronic components 26.

The circuit modules 10 and 10a to 10g each include the plurality of electronic components 24. However, the circuit modules 10 and 10a to 10g each only need to include one or more electronic components 24.

The circuit modules 10c, 10d, 10e, and 10g each include the plurality of third solder balls 34. However, the circuit modules 10b, 10d, 10e, and 10g each only need to include one or more third solder balls 34.

The second sealing resin 16 and the third sealing resin 20 are not essential components.

The electronic component 22 and the electronic component 28 are not essential components.

The first solder ball 30, the second solder ball 32, and the third solder ball 34 may have an ellipsoidal shape other than a spherical shape. In this case, the size of the solder ball is the maximum width of the solder ball in the direction orthogonal to the up-down direction.

In the circuit module 10a, the plurality of second solder balls 32 may have the bottom surface Sd that is a plane orthogonal to the up-down direction (Z-axis direction). In this case, in the circuit module 10a, the bottom surfaces Sd of the plurality of second solder balls 32 are included in one plane together with the lower main surface S51 (positive main surface) of the third sealing resin 20.

The circuit module 10a may include the shield conductor 50. In this case, the shield conductor 50 covers the upper surface (negative main surface) of the second sealing resin 16 and the side surfaces of the second sealing resin 16 located in the direction orthogonal to the up-down direction (Z-axis direction), the side surfaces of the lower circuit board 14 (first circuit board) located in the direction orthogonal to the Z-axis direction, the side surfaces of the first sealing resin 18 located in the direction orthogonal to the up-down direction (Z-axis direction), and the side surfaces of the upper circuit board 12 (second circuit board) located in the direction orthogonal to the up-down direction (Z-axis direction).

When the circuit module 10a includes the shield conductor 50, at least one of the plurality of first solder balls 30 may be in contact with the shield conductor 50.

In the circuit modules 10 and 10a to 10g, the size of the first solder ball 30 is not necessarily larger than the size of the second solder ball 32.
10, 10a to 10g circuit module
12 upper circuit board
12a, 14a board body
12b, 12c, 14b, 14c mounting electrode
14 lower circuit board
24, 26 electronic component
30 first solder ball
A1 inter-board region
S1 first upper main surface
S11 second upper main surface
S12 second lower main surface
S2 first lower main surface
S31 third upper main surface
S32 third lower main surface
S41 fourth upper main surface
S42 fourth lower main surface

1. A circuit module comprising:
a first circuit board including a first positive main surface and a first negative main surface arranged in a Z-axis direction, the first positive main surface being located in a positive direction of a Z-axis with respect to the first negative main surface;
a second circuit board including a second positive main surface and a second negative main surface arranged in the Z-axis direction, the second circuit board being located in a negative direction of the Z-axis with respect to the first circuit board and overlapping the first circuit board when viewed in the Z-axis direction, the second positive main surface being located in the positive direction of the Z-axis with respect to the second negative main surface;
a first electronic component mounted on the second positive main surface, the first electronic component including a third positive main surface and a third negative main surface arranged in the Z-axis direction, the third positive main surface being located in the positive direction of the Z-axis with respect to the third negative main surface; and
one or more first solder balls each having an ellipsoidal shape, the one or more first solder balls being located in an inter-board region between the first circuit board and the second circuit board and electrically connecting the first circuit board and the second circuit board,
wherein the circuit module has a structure of (A) or (B):
(A) the third positive main surface of the first electronic component is in contact with the first negative main surface of the first circuit board,
(B) the circuit module further comprising a second electronic component mounted on the first negative main surface, the second electronic component including a fourth positive main surface and a fourth negative main surface arranged in the Z-axis direction, the fourth positive main surface being located in the positive direction of the Z-axis with respect to the fourth negative main surface,
wherein the third positive main surface of the first electronic component is in contact with the fourth negative main surface of the second electronic component.

2. The circuit module according to claim 1, further comprising a first sealing resin provided in the inter-board region so as to be in contact with the first negative main surface and the second positive main surface and cover surfaces of the one or more first solder balls.

3. The circuit module according to claim 2,
wherein the circuit module further includes:
a second sealing resin covering the first positive main surface; and
a shield conductor covering a positive main surface of the second sealing resin, a side surface of the second sealing resin located in a direction orthogonal to the Z-axis direction, a side surface of the first circuit board located in the direction orthogonal to the Z-axis direction, a side surface of the first sealing resin located in the direction orthogonal to the Z-axis direction, and a side surface of the second circuit board located in the direction orthogonal to the Z-axis direction.

4. The circuit module according to claim 3, wherein at least one of the one or more first solder balls is in contact with the shield conductor.

5. The circuit module according to claim 1,
wherein the circuit module further includes one or more second solder balls each having an ellipsoidal shape, the one or more second solder balls being provided on the second negative main surface of the second circuit board, and
wherein a size of the one or more first solder balls is larger than a size of the one or more second solder balls.

6. The circuit module according to claim 1,
wherein the circuit module further includes:
one or more second solder balls each having an ellipsoidal shape, the one or more second solder balls being provided on the second negative main surface of the second circuit board; and
a third sealing resin covering the second negative main surface, wherein the one or more second solder balls each have a bottom surface being a plane orthogonal to the Z-axis direction, and
wherein the bottom surface of the one or more second solder balls is included in one plane together with a negative main surface of the third sealing resin.

7. The circuit module according to claim 2,
wherein the circuit module further includes:
a second sealing resin covering the second negative main surface; and
a shield conductor covering a negative main surface of the second sealing resin, a side surface of the second sealing resin located in a direction orthogonal to the Z-axis direction, a side surface of the first circuit board located in the direction orthogonal to the Z-axis direction, a side surface of the first sealing resin located in the direction orthogonal to the Z-axis direction, and a side surface of the second circuit board located in the direction orthogonal to the Z-axis direction.

8. The circuit module according to claim 7, wherein at least one of the one or more first solder balls is in contact with the shield conductor.

9. The circuit module according to claim 1,
wherein the circuit module further includes one or more second solder balls each having an ellipsoidal shape, the one or more second solder balls being provided on the first positive main surface of the first circuit board, and
wherein a size of the one or more first solder balls is larger than a size of the one or more second solder balls.

10. The circuit module according to claim 1,
wherein the circuit module includes:
one or more second solder balls each having an ellipsoidal shape, the one or more second solder balls being provided on the first positive main surface of the first circuit board; and
a third sealing resin covering the first positive main surface,
wherein the one or more second solder balls each have a bottom surface being a plane orthogonal to the Z-axis direction, and
wherein the bottom surface of the one or more second solder balls is included in one plane together with a positive main surface of the third sealing resin.

11. The circuit module according to claim 1,
wherein the circuit module further includes one or more third solder balls each having an ellipsoidal shape, located in the inter-board region between the first circuit board and the second circuit board, and electrically connecting the first circuit board and the second circuit board,
wherein the one or more first solder balls are in contact with a mounting electrode of the second circuit board,
wherein the one or more third solder balls are in contact with a mounting electrode of the first circuit board,
wherein the one or more first solder balls and the one or more third solder balls are arranged in the Z-axis direction and are in contact with each other, and
wherein a contact portion where the one or more first solder balls and the one or more third solder balls are in contact with each other is surrounded by an outer edge of the one or more first solder balls and an outer edge of the one or more third solder balls when viewed in the Z-axis direction.

12. The circuit module according to claim 2,
wherein the circuit module further includes one or more second solder balls each having an ellipsoidal shape, the one or more second solder balls being provided on the second negative main surface of the second circuit board, and
wherein a size of the one or more first solder balls is larger than a size of the one or more second solder balls.

13. The circuit module according to claim 3,
wherein the circuit module further includes one or more second solder balls each having an ellipsoidal shape, the one or more second solder balls being provided on the second negative main surface of the second circuit board, and
wherein a size of the one or more first solder balls is larger than a size of the one or more second solder balls.

14. The circuit module according to claim 4,
wherein the circuit module further includes one or more second solder balls each having an ellipsoidal shape, the one or more second solder balls being provided on the second negative main surface of the second circuit board, and
wherein a size of the one or more first solder balls is larger than a size of the one or more second solder balls.

15. The circuit module according to claim 2,
wherein the circuit module further includes:
one or more second solder balls each having an ellipsoidal shape, the one or more second solder balls being provided on the second negative main surface of the second circuit board; and
a third sealing resin covering the second negative main surface, wherein the one or more second solder balls each have a bottom surface being a plane orthogonal to the Z-axis direction, and
wherein the bottom surface of the one or more second solder balls is included in one plane together with a negative main surface of the third sealing resin.

16. The circuit module according to claim 3,
wherein the circuit module further includes:
one or more second solder balls each having an ellipsoidal shape, the one or more second solder balls being provided on the second negative main surface of the second circuit board; and
a third sealing resin covering the second negative main surface, wherein the one or more second solder balls each have a bottom surface being a plane orthogonal to the Z-axis direction, and
wherein the bottom surface of the one or more second solder balls is included in one plane together with a negative main surface of the third sealing resin.

17. The circuit module according to claim 4,
wherein the circuit module further includes:
one or more second solder balls each having an ellipsoidal shape, the one or more second solder balls being provided on the second negative main surface of the second circuit board; and
a third sealing resin covering the second negative main surface, wherein the one or more second solder balls each have a bottom surface being a plane orthogonal to the Z-axis direction, and
wherein the bottom surface of the one or more second solder balls is included in one plane together with a negative main surface of the third sealing resin.

18. The circuit module according to claim 5,
wherein the circuit module further includes:
one or more second solder balls each having an ellipsoidal shape, the one or more second solder balls being provided on the second negative main surface of the second circuit board; and
a third sealing resin covering the second negative main surface, wherein the one or more second solder balls each have a bottom surface being a plane orthogonal to the Z-axis direction, and
wherein the bottom surface of the one or more second solder balls is included in one plane together with a negative main surface of the third sealing resin.

19. The circuit module according to claim 2,
wherein the circuit module further includes one or more second solder balls each having an ellipsoidal shape, the one or more second solder balls being provided on the first positive main surface of the first circuit board, and
wherein a size of the one or more first solder balls is larger than a size of the one or more second solder balls.

20. The circuit module according to claim 7,
wherein the circuit module further includes one or more second solder balls each having an ellipsoidal shape, the one or more second solder balls being provided on the first positive main surface of the first circuit board, and
wherein a size of the one or more first solder balls is larger than a size of the one or more second solder balls.
